(19) United States
(12) Patent Application Publication
(10) Pub. No.: US 2008/0050926 A1
(43) Pub. Date: Feb. 28, 2008

(54) Dry etching method

(76) Inventor: Hideo Nakagawa, Shiga (JP)

Correspondence Address: MCDERMOTT WILL & EMERY LLP, 600 13TH STREET, NW, WASHINGTON, DC, 20005-3096, US

(21) Appl. No.: 11/798,087

(22) Filed: May 10, 2007

(30) Foreign Application Priority Data
Aug. 25, 2006 (JP) 2006-228909

(51) Int. Cl. H01L 21/302

(52) U.S. Cl. 438/710; 257/E21.214

(57) ABSTRACT

In dry etching an insulating film containing silicon and carbon and formed on a wafer, plasma is generated from a mixed gas of a first molecule gas containing carbon and fluorine and a second molecule gas containing nitrogen. At this time, an RF bias of 2 MHz or lower is applied to an electrode on which the wafer is placed.

### FIELD OF THE INVENTION

The present invention relates to dry etching methods, and particularly relates to a method for etching an insulating film of which main compositions are Si and C.

### BACKGROUND ART

In recent years, low dielectric constant insulating films (low-k films) are used as insulating films for wirings for improving circuit delay accompanied by miniaturization of semiconductor integrated circuit devices. Presently, in CMOS (Complementary Metal-Oxide Semiconductor) devices under 65 nm design rule, SiOC films are used widely as the low-k films. For etching SiOC films, resists for ArF exposure are used.

The resists for ArF exposure, however, involve a disadvantage of low etching resistance.

A conventional SiOC film dry etching method will be described with reference to FIG. 9A to FIG. 9D.

In general, a dry etching apparatus shown in FIG. 9A includes a vacuum reaction chamber 101 capable of keeping a reduced pressure state by generating constant gas flow, a plasma source 102 provided at the upper part of the vacuum reaction chamber 101, for generating plasma 103, and an electrode 105 provided at the lower part of the vacuum reaction chamber 101 for holding a wafer 104. An insulator 106 intervenes between the electrode 105 and the bottom of the vacuum reaction chamber 101, and the electrode 105 is connected to an RF power source 107 used as an RF bias generating source for extracting ion from the plasma.

The plasma source 102 may be, according to the principle of plasma generation, a capacitive coupling plasma source, an inductive coupling plasma source, a microwave plasma source, a plasma source utilizing resonance, such as an ECR (Electron Cyclotron Resonance), or the like. As the RF power source 107, a power source may be used which generates bias having a frequency equal to or smaller than at least the frequency used in the plasma source 102.

Patent Document 1 indicates that a SiO₂ film can be etched at a RF bias of 100 kHz with a capacitive coupling plasma of 13.56 MHz generated. Patent Document 2 suggests that a SiO₂ film can be etched with the use of a microwave plasma source when a RF bias of 400 kHz is applied. Further, Patent Document 3 discloses a method of performing etching while modifying a reactive etched surface of a SiOC film by eliminating a carbon component from the surface with the use of a fluorocarbon gas and a gas containing nitrogen, such as N₂.

The conventional technique for etching a SiOC film will be described below with reference to FIG. 9B to FIG. 9D. FIG. 9B to FIG. 9D are enlarged views of a region 108 around the surface of the wafer 104 in FIG. 9A, wherein FIG. 9B shows a structure of the surface portion of the wafer before etching, and FIG. 9C and FIG. 9D shows examples of results by the conventional etching.

As shown in FIG. 9B, a SiOC film 110 as a to-be-etched film is formed on a substrate 109 composed of the wafer 104, and a resist pattern 111 having a hole pattern is formed on the SiOC film 110.

In the conventional etching condition, the selectivity over a resist (a ratio of an etching rate of the SiOC film 110 as a to-be-etched film to an etching rate of the resist) is small, and therefore, the resist film 111a remaining on the SiOC film 110a after etching is small in thickness, as shown in FIG. 9C. Hereinafter, selectivity over a resist and an etching rate of a resist are referred to as resist selectivity and a resist etching rate, respectively. Further, if the resist selectivity is rather small, the edges of the resist 111b remaining on the SiOC film 110b after etching are etched away, with a result that the upper part of the SiOC film 110b is also etched to increase the opening area of the holes.

One example of conventional etching conditions is as follows:

[Conventional Etching Conditions 1]

Gas flow rate: CF₄/C₄F₈/N₂=50/10/50 (cm³/min. (standard conditions))

Pressure: 1.33 (Pa)

Microwave power: 2500 (W) [frequency: 2.45 GHz]

Bias power: 400 (W) [frequency: 13.56 MHz]

Substrate temperature: approximately 80° C.

Results of etching under the above conditions are shown in FIG. 10A and FIG. 10B. FIG. 10A shows a result of hole pattern formation by etching under the above conditions, and FIG. 10B shows a result of trench pattern formation by etching under the above conditions. FIG. 10A and FIG. 10B show partial etched states, namely, states of where etching is performed incompletely and is suspended in the middle. The diameter of the hole to be formed by etching is approximately 130 nm, and the width of the trench to be formed by etching is approximately 260 nm. The initial film thickness of the resist is approximately 360 nm, and the film thickness of the SiOC film as a to-be-etched film is approximately 383 nm.

In hole formation shown in FIG. 10A, the etching rate of the SiOC film is 279 nm/min. while the resist etching rate is 174 nm/min., which means 1.6 resist selectivity.

In trench formation shown in FIG. 10B, the etching rate of the SiOC film is 395 nm/min. while the resist etching rate is 188 nm/min., which means 2.1 resist selectivity.

Patent Document 1: U.S. Pat. No. 4,464,223

Patent Document 2: Japanese Patent Publication No. 3042208B

Patent Document 3: Japanese Patent Publication No. 3400770B

### SUMMARY OF THE INVENTION

When an insulting film of which main compositions are Si and C, such as a SiOC film or the like is etched, especially, when such an insulating film is etched with the use of a resist for ArF exposure, however, undesirable reduction in thickness of the resist by etching is caused due to low resist selectivity, as described above, resulting in an undesirably etched shape (see FIG. 9D). This problem is more significant in over-etching that is practically performed in the present day.

For example, in forming a hole pattern by etching an SiOC film having an initial film thickness of 383 nm under the aforementioned conventional conditions, 30% over-etching (498 nm in thickness) etches the resist having an initial film thickness of 360 nm by 311 nm (=498/1.6), so that the remaining resist after etching has a thickness of 49 nm.

While, in forming a trench pattern by etching an SiOC film having an initial film thickness of 383 nm under the aforementioned conventional conditions, 30% over-etching (498 nm in thickness) etches the resist having an initial film thickness of 360 nm by 237 nm (=498/2.1), so that the remaining resist after etching has a thickness of 123 nm.

Moreover, the above described problems become more significant when the initial film thicknesses of resists become smaller in association with progress in miniaturization.

In view of the foregoing, the present invention has its object of increasing resist selectivity in etching an insulating film of which main compositions are Si and C.

To achieve the above object, a first drying etching method according to the present invention is a dry etching method for dry etching an insulating film containing silicon and carbon and formed on a wafer, including the steps of: applying a RF bias of 2 MHz or lower to an electrode on which the wafer is placed while generating plasma from a mixed gas of a first molecule gas containing carbon and fluorine and a second molecule gas containing nitrogen.

In the first dry etching method of the present invention, the RF bias frequency is set to 2 MHz or lower to increase dispersion of energy distribution of ions in the plasma, thereby substantially reducing the number of ions having high energy. Accordingly, the sputtering rate of the resist by the ions lowers to lower the resist etching rate. As a result, the resist selectivity increases substantially, preventing the resist from being thinned by etching to attain a desired etched shape.

A second dry etching method of the present invention is a dry etching method for dry etching an insulating film containing silicon and carbon and formed on a wafer, including the steps of: applying RF bias to an electrode on which the wafer is placed while generating plasma from a mixed gas of a first molecule gas containing carbon and fluorine and a second molecule gas containing nitrogen, wherein the RF bias has a frequency that produces a peak-to-peak voltage of ion energy distribution in the plasma, and the peak-to-peak voltage is twice larger than that when an RF bias having a frequency of 13.56 MHz is applied to the electrode.

A third dry etching method of the present invention is a dry etching method for dry etching an insulating film containing silicon and carbon and formed on a wafer, including the steps of: applying a RF bias to an electrode on which the wafer is placed so as to set a peak-to-peak voltage of ion energy distribution in the plasma to 200 eV or higher while generating plasma from a mixed gas of a first molecule gas containing carbon and fluorine and a second molecule gas containing nitrogen.

In the second and third dry etching methods, dispersion of energy distribution of ions in the plasma is increased to reduce substantially the number of ions having high energy. Accordingly, the sputtering rate of the resist by the ions lowers to lower the resist etching rate. As a result, the resist selectivity increases substantially, preventing the resist from being thinned by etching to attain a desired etched shape.

In any of the first to third dry etching of the present invention, it is preferable to set a maximum energy of incident ions to the insulating film from the plasma by the RF bias is set to 600 eV or lower.

This lowers the sputtering rate of the resist by ions to lower the resist etching rate. As a result, the resist selectivity increases, and the surface roughness of the resist, which would cause abnormal etching, is notably less observed.

In any of the first to third dry etching method of the present invention, it is preferable that the mixed gas further contains a hydrocarbon molecule gas.

With the above arrangement, the surface of the resist is covered with a non-dissociated hydrocarbon gas and dissociated hydrocarbon molecules, so that the resist selectivity increases further. Specifically, double synergetic effect with effect by low frequency RF bias of 2 MHz or lower or triple synergetic effect with the effect by low frequency RF bias of 2 MHz or lower and effect by low ion energy of 600 eV or lower increases the resist selectivity effectively. In this case, if the hydrocarbon molecule gas is CH₄, C₂H₄, or C₂H₆, not only the resist selectivity increases but also the gas mixing ratio of the mixed gas can be easily adjusted, facilitating handling thereof. Further, in this case, a gas containing fluorine and a hydrocarbon molecule may be used in place of the first molecule gas and the hydrocarbon molecule gas.

In any of the first to third dry etching of the present invention, the first molecule gas may be a fluorocarbon gas or a hydride fluorocarbon gas.

In any of the first to third dry etching of the present invention, the second molecule gas may be a molecule gas of nitrogen or an ammonia gas.

With the above arrangement, nitrogen supply can be controlled easily, thereby widening a process window.

In any of the first to third dry etching of the present invention, the second molecule gas is preferably a molecule gas containing C—N bonds and hydrogen, such as an amine compound gas, a nitrile compound gas, or the like.

With this arrangement, not only nitrogen but also hydrocarbon molecules can be supplied to the plasma. As a result, the hydrocarbon molecule gas forms a protection film on the surface of the resist, thereby increasing the resist selectivity furthermore.

In any of the first to third dry etching of the present invention, a gas containing fluorine and nitrogen may be used in place of the first molecule gas and the second molecule gas.

In any of the first to third dry etching of the present invention, it is preferable that the mixed gas further contains a rare gas.

With the above arrangement, effect of diluting the gas concentration in a vacuum reaction chamber by adding the rare gas suppresses the growth rate of the deposited film on the wall of the reaction chamber to shorten the time required for cleaning, thereby achieving an increase in running time as a whole.

In any of the first to third dry etching of the present invention, it is preferable that the insulating film is a SiOC film, a SiOCN film, a SiCO film, SiCON film, a SiC film or a SiCN film.

With the above arrangement, the reactive etched surface of the insulating film, such as a SiOC film, (hereinafter referred typically to as a SiOC film) is allowed to be SiO₂ by removing C from the reactive surface by nitrogen atoms or nitrogen molecule ions generated from the plasma composed of the mixed gas of the molecule gas containing carbon and fluorine and the molecule gas containing nitrogen while efficient etching is performed on the SiO₂ portion by the fluorocarbon molecules generated from the plasma. Accordingly, the SiOC film can be etched at high speed by ions of which energy is lower than that in etching to a SiO₂ film. Thus, high-speed etching to the SiOC film is enabled while the resist selectivity increases with the use of the low-frequency RF bias of 2 MHz or lower, so that the SiOC film is etched at high resist selectivity.

As described above, in the present invention, high-speed etching is enabled with the use of the plasma composed of the mixed gas of the molecule gas containing carbon and fluorine and the molecule gas containing nitrogen even at low ion energy. Accordingly, when a low-frequency RF bias of, for example, 2 MHz or lower is used, the low ion energy component increases, namely, the high energy component reduces, resulting in increased resist selectivity. When the ion energy is set to 600 eV or lower, the resist selectivity increases more effectively. Addition of the hydrocarbon molecule gas for supplying hydrocarbon molecules onto the surface of the resist promotes formation of the protection film on the surface of the resist, thereby further increasing the resist selectivity.

In short, the present invention relating to a dry etching method using plasma achieves increased resist selectivity especially when applied to etching of an insulating film of which main compositions are Si and C and is very useful therefore.

### BRIEF DESCRIPTION OF THE DRAWINGS

FIG. 1A is a schematic configuration diagram of a dry etching apparatus for performing a dry etching method according to Embodiment 1 of the present invention, and FIG. 1B and FIG. 1C are sectional views showing respective steps of the dry etching method according to Embodiment 1 of the present invention.

FIG. 2A to FIG. 2C are photos for explaining effects obtained when a hole pattern is formed by etching an SiOC film by the dry etching method according to Embodiment 1 of the present invention.

FIG. 3A to FIG. 3C are photos for explaining effects obtained when a trench pattern is formed by etching an SiOC film by the dry etching method according to Embodiment 1 of the present invention.

FIG. 4A and FIG. 4B are graphs for explaining effects by low frequency RF bias in the dry etching method according to Embodiment 1 of the present invention.

FIG. 5A to FIG. 5C are photos for explaining effects obtained when a hole pattern is formed by etching an SiOC film by a dry etching method according to Embodiment 2 of the present invention.

FIG. 6A to FIG. 6C are photos for explaining effects obtained when a trench pattern is formed by etching an SiOC film by the dry etching method according to Embodiment 2 of the present invention.

FIG. 7A to FIG. 7C are graphs for explaining effects by low frequency RF bias in the dry etching method according to Embodiment 2 of the present invention.

FIG. 8A is a sectional view showing one example of a result of hole etching by a conventional technique, and FIG. 8B is a sectional view showing one example of a result of hole etching by the dry etching method according to Embodiment 2 of the present invention.

FIG. 9A is a schematic configuration diagram of a dry etching apparatus for performing a conventional dry etching method, and FIG. 9B to FIG. 9D are sectional views showing respective steps of the conventional dry etching method.

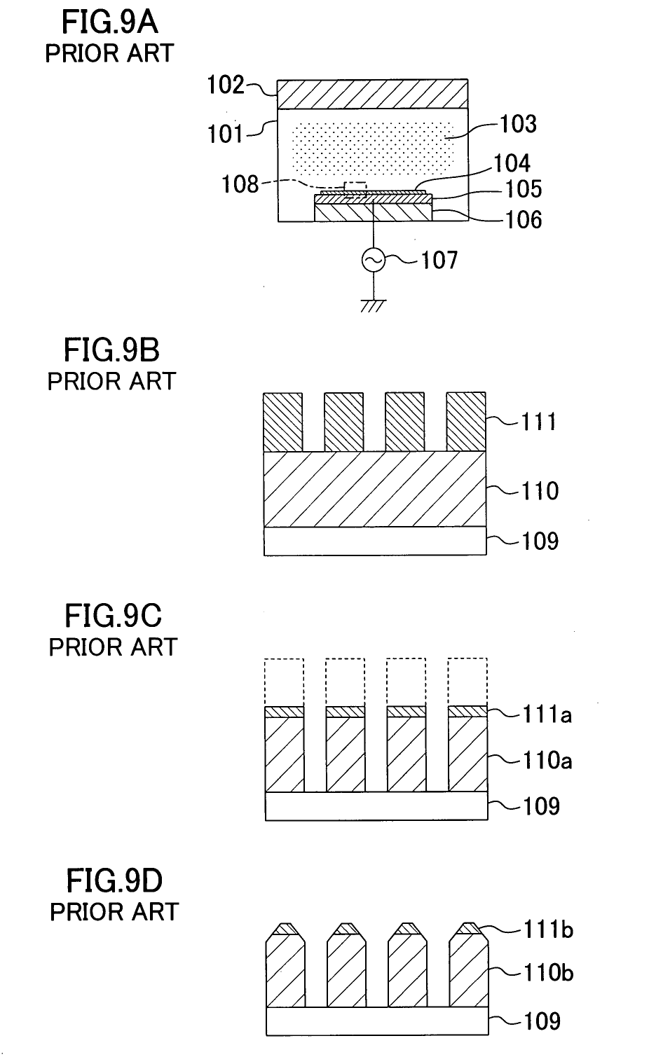

FIG. 10A is a photo showing a result of hole pattern formation by the conventional dry etching method, and FIG. 10B is a photo showing a result of trench pattern formation by the conventional dry etching method.

### DESCRIPTION OF THE PREFERRED EMBODIMENTS

### Embodiment 1

A dry etching method according to Embodiment 1 of the present invention will be described with reference to the drawings by referring to the case where a to-be-etched film is a SiOC film.

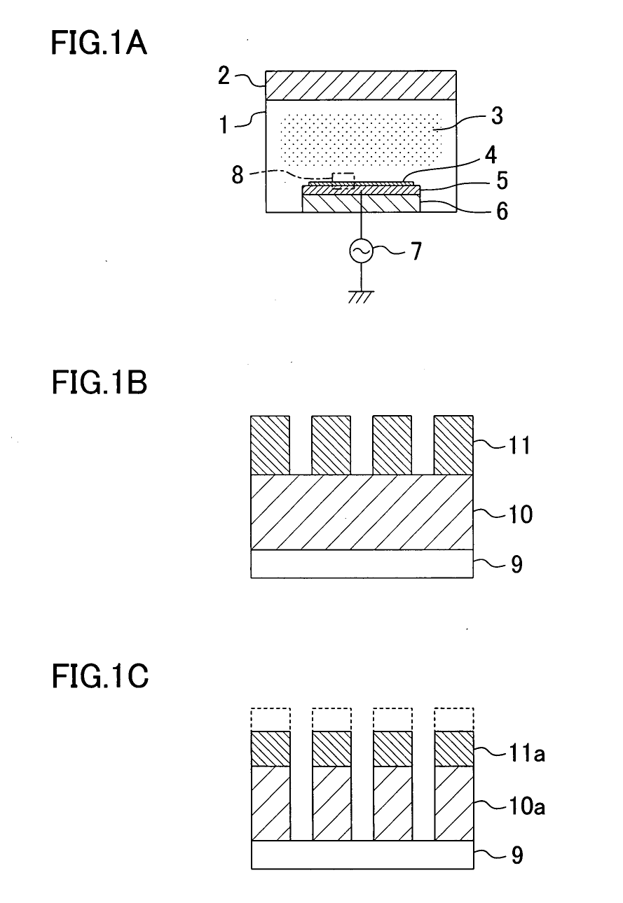

FIG. 1A is a schematic configuration diagram of a dry etching apparatus for performing the dry etching method according to the present embodiment.

In the dry etching apparatus used in the present embodiment shown in FIG. 1A, a plasma source 2 for generating plasma 3 is provided at the upper part of a vacuum reaction chamber 1 capable of keeping a reduced pressure state by generating constant gas flow while an electrode 5 for holding a wafer 4 is provided at the lower part of the vacuum reaction chamber 1. An insulator 6 intervenes between the electrode 5 and the bottom of the vacuum reaction chamber 1, and the electrode 5 is connected to an RF power source 7 used as an RF bias generating source for extracting ions from the plasma 3.

The plasma source 2 may be a capacitive coupling plasma source of RIE (Reactive Ion Etching) type, a dual frequency RIE type, magnetron enhanced RIE (MERIE) type, or the like, an inductive coupling plasma source, a microwave plasma source, a plasma source utilizing resonance, such as an ECR (Electron Cyclotron Resonance) or the like, a NLD (Neutral Loop Discharge) plasma source, a helicon wave plasma source, or the like. It should be noted that the plasma source 2 is not limited to the above listed plasma sources.

The feature of the present embodiment lies in that a power source at a frequency of 2 MHz or lower is used as the RF power source 7 for achieving the object of the present invention, namely, for increasing the resist selectivity (a ratio of an etching rate of a SiOC film as a to-be-etched film to a resist etching rate). The reason why such an RF power source is used will be described later in detail. The frequency of the RF power source 7 is preferably 1 MHz or 800 kHz or lower, more preferably, 400 kHz or lower. In practical use, an optimum frequency is selected for use from frequencies in the range not exceeding 2 MHz with etching characteristics other than the resist selectivity taken into consideration.

In the present embodiment, a mixed gas of a first molecule gas containing carbon and fluorine and a second molecule gas containing nitrogen is used as an etching gas for generating the plasma 3.

The first molecule gas containing carbon and fluorine may be a fluorocarbon gas, a hydride fluorocarbon gas, or a plurality of gases selected therefrom. The fluorocarbon gas may be CF₄, C₂F₆, C₃F₈, C₄F₆, C₄F₈, C₅F₈, or the like. The hydride fluorocarbon gas may be CHF₃, CH₂F₂, CH₃F, or the like.

The second molecule gas containing nitrogen may be nitrogen molecules (N₂) or ammonia (NH₃). With the use thereof, nitrogen supply can be controlled easily to widen a process window.

Optionally, an amine compound gas, a nitrile compound gas, or the like may be used as the second molecule gas containing nitrogen. The molecules composing the aforementioned gases have a significant feature that C—N bonds and hydrogen atoms are contained.

The amine compound gas as the gas of molecules containing C—N bonds and hydrogen atoms may be alkylamine [RNH₂], dialkylamine [R₁(R₂)NH], and trialkylamine [R₁(R₂)(R₃)N]. The alkyl group R may be either a straight-chain alkyl group or a cyclic alkyl group. The alkylamine includes, for example, methylamine [CH₃NH₂ having a boiling point of −6.33° C. at one atmospheric pressure (760 mmHg, hereinafter the same is applied)], ethylamine [C₂H₅NH₂ having a boiling point of 16.6° C. at one atmospheric pressure], n-propylamine [CH₃(CH₂)₂NH₂ having a boiling point of 48° C. at one atmospheric pressure], isopropylamine [(CH₃)₂CHNH₂ having a boiling point of 33.5° C. at one atmospheric pressure], 3-dimetyleamino propylamine [(CH₃)₂NCH₂CH₂CH₂NH₂ having a boiling point of 135° C. at one atmospheric pressure], n-butylamine [CH₃(CH₂)₃NH₂ having a boiling point of 68.5° C. at one atmospheric pressure], isobutylamine [(CH₃)₂CH—CH₂NH₂ having a boiling point of 78° C. at one atmospheric pressure], and the like. The dialkylamine includes, for example, dimetylamine [(CH₃)₂NH having a boiling point of 6.9° C. at one atmospheric pressure], diethylamine [(C₂H₅)₂NH having a boiling point of 55.4° C. at one atmospheric pressure], di-n-propylamine [CH₃(CH₂)₂NH₂ having a boiling point of 48° C. at one atmospheric pressure], diisopropylamine [CH₃—CH(CH₃)—NH—CH(CH₃)—CH₃ having a boiling point of 84° C. at one atmospheric pressure], sec-butylamine [CH₃CH(NH₂)C₂H₅ having a boiling point of 63° C. at one atmospheric pressure], di-n-butylamine [(CH₃CH₂CH₂CH)₂NH having a boiling point of 159° C. at one atmospheric pressure], diisobutylamine [CH₃CH(CH₃)CH₂NHCH₂CH(CH₃)CH₃ having a boiling point of 140° C. at one atmospheric pressure], and the like. The trialkylamine includes, for example, trimethylamine [(CH₃)₃N having a boiling point of 3° C. at one atmospheric pressure], triethylamine [(C₂H₅)₃N having a boiling point of 89.5° at one atmospheric pressure], tributyleamine [(CH₃CH₂CH₂CH₂)₃N having a boiling point of 216.5° C. at one atmospheric temperature], and the like. As the gas having a cyclic alkyl group, aniline [C₆H₅NH₂ having a boiling point of 184° C. at one atmospheric pressure] or the like may be used. Alternatively, a gas having two or more amines may be used, such as ethylenediamine [H₂NCH₂CH₂NH₂ having a boiling point of 117° C. at one atmospheric pressure], or the like.

The nitrile compound gas as the gas composed of molecules containing C—N bonds and hydrogen atoms includes acetonitrile [CH₃CN having a boiling point of 82° C. at one atmospheric pressure], acrylonitril [CH₂═CH—CN having a boiling point of 77° C. at one atmospheric pressure], and the like. In addition, as the gas composed of molecules containing C—N bonds and hydrogen atoms, there may be used: an imine compound, such as ethylene imine [CH₂NHCH₂ having a boiling point of 56.5° C. at one atmospheric pressure], propylene imine [C₃H₇N having a boiling point of 77° C. at one atmospheric pressure], or the like; a hydrazine compound, such as methyl hydrazine [CN₃NHNH₂ having a boiling point of 87.5° C. at one atmospheric pressure], 1,1-dimethyl hydrazine [NH₂—N(CH₃)₂ having a boiling point of 63° C. at one atmospheric pressure], or the like; or an amide compound, such as N,N-dimethyl acetamide [CH₃CON(CH₃)₂ having a boiling point of 165° C. at one atmospheric pressure], N,N-dimethylformamido [HCON(CH₃)₂ having a boiling point of 153° C. at one atmospheric pressure], or the like. Hydrogen cyanide [HCN having a boiling point of 26° C. at one atmospheric pressure], which is the smallest gas containing C—N bonds and hydrogen atoms, may be used, of course, but is the most hazardous gas in terms of safety. For using any of the above gases, it is practical, even if the gas has a high boiling point, to change the gas from the liquid state or the solid state to the gaseous state immediately before supplying it to the reaction chamber and then to supply it to the reaction chamber. Wherein, more convenient gases in view of safe gas supply are gases having boiling points of around 100° C. or lower.

In the present embodiment, needless to say, two or more of the aforementioned gases may be mixed as the second molecule gas containing nitrogen. With any of these gases, not only nitrogen but also hydrocarbon molecules can be supplied to the plasma 3. As a result, the molecule gas of hydrocarbon forms a protection film on the surface of the resist to increase the resist selectivity.

In the present embodiment, the first molecule gas containing carbon and fluorine and the second molecule gas containing nitrogen may be replaced by a gas containing fluorine and nitrogen, for example, NF₃, N₂F, or the like. Even with this arrangement, the SiOC film can be etched efficiently, thereby increasing the resist selectivity.

Further, in the present embodiment, it is preferable to add a molecule gas of hydrocarbon to the first molecule gas containing carbon and fluorine and the second molecule gas containing nitrogen for generating the plasma 3. The molecule gas of hydrocarbon includes saturated hydrocarbon having single bonds (C—C) (CₙH₂ₙ₊₂ (n is an integer): CH₄, C₂H₆, C₃H₈, and so on), unsaturated hydrocarbon having double bonds (C═C) (CₙH₂ₙ (n is an integer larger than 1): C₂H₄, C₃H₆, and so on), or unsaturated hydrocarbon having triple bonds (C≡C) (CₙH₂ₙ₋₂ (n is an integer larger than 1): C₂H₂, C₃H₄, and so on). The hydrocarbon molecules may be in a straight chain form or a cyclic form. With the above arrangement, an undissociated hydrocarbon gas and dissociated hydrocarbon molecules cover the surface of the resist to increase the resist selectivity further. Specifically, an effective increase in resist selectivity can be achieved by double synergetic effect with effect by a low frequency RF bias of 2 MHz or lower, which will be described later, or triple synergetic effect with the effect by a low frequency RF bias of 2 MHz or lower and effect by a low ion energy of 600 eV or lower, which will be described later. When the molecule gas of hydrocarbon is CH₄, C₂H₄, or C₂H₆, the mixing ratio of the mixed gas can be adjusted easily in addition to the effect of an increase in resist selectivity, thereby facilitating handling.

Moreover, in the present embodiment, the first molecule gas containing carbon and fluorine and the molecule gas of hydrocarbon may be replaced by a gas containing fluorine and hydrocarbon molecules. Specifically, for example, any of the following gas may be used: HFE-227me (CF₃OCHFCF₃); tetrafluorooxetane (CF₂CF₂OCH₂); hexafluoroisopropanol ((CF₃)₂CHOH); HFE-245mf (CF₂CH₂OCHF₂); HFE-347mcf (CHF₂OCH₂CF₂CF₃); HFE-245mc (CHF₃OCF₂CF₃); HFE-347mf-c (CF₃CH₂OCF₂CF₂H HFE-236me (CHF₂OCH₂CHFCF₃); and the like. These gases are gases having a small global warming coefficients for anti-global warming, which means environmentally friendly gases.

Furthermore, in the present embodiment, it is preferable to add a rare gas (He, Ne, Ar, Kr, Xe, or Rn) further to the first molecule gas containing carbon and fluorine and the second molecule gas containing nitrogen for generating the plasma 3. As the rare gas, Ar may be used, for example. When He, Ne, Ar, Kr, Xe, or Rn is added as the rare gas, the electron temperature in the plasma 3 can be increased or reduced. The electron temperature of rare gas plasma depends largely on the first ionization energy of the rare gas. Accordingly, a rare gas having a smaller atomic number is selected for generating plasma 3 of which electron temperature is high, or a rare gas having a larger atomic number is selected for generating plasma 3 of which electron temperature is low. Two or more rare gases may be mixed for use.

FIG. 1B and FIG. 1C are sectional views showing respective steps of the dry etching method according to the present embodiment. Specifically, FIG. 1B and FIG. 1C are enlarged views of a region 8 around the surface of the wafer 4 in FIG. 1A, wherein FIG. 1B shows a structure of the surface portion of the wafer 4 before etching, and FIG. 1C shows one example of a result of etching by the dry etching method according to the present embodiment.

As shown in FIG. 1B, a SiOC film 10 as a to-be-etched film is formed on a substrate 9 composed of the wafer 4, and a resist pattern 11 having a hole pattern is formed on the SiOC film 10.

When the etching method of the present embodiment is employed, the resist selectivity (a ratio of an etching rate of the SiOC film 10 as a to-be-etched film to a resist etching rate) increases, as will be described later in detail. Accordingly, as shown in FIG. 1C, the resist 11a remaining on the SiOC film 10a after etching increases in thickness. This prevents processing abnormality and dimensional abnormality caused due to regression (thinning) of the resist 11a, thereby enabling highly precise and safe etching to the SiOC film 10.

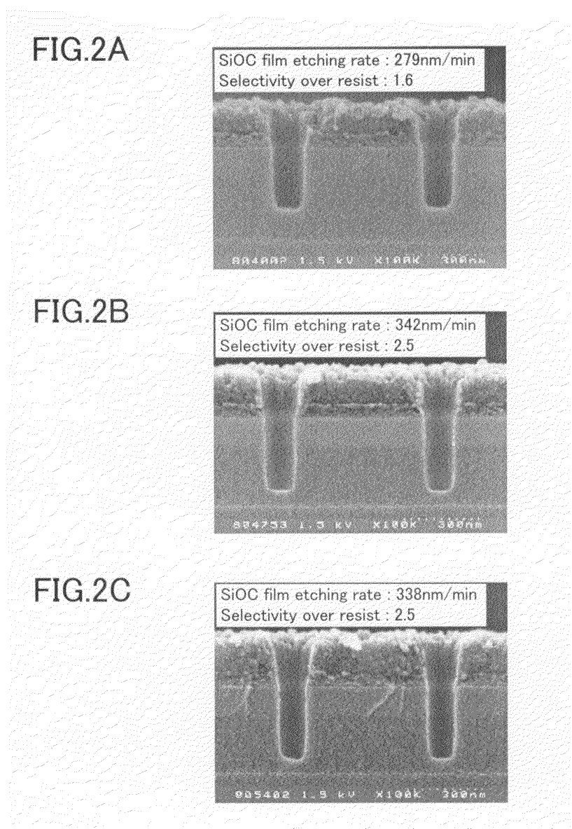

FIG. 2A to FIG. 2C are photos for explaining effects obtained when a hole pattern is formed by etching a SiOC film by the dry etching method of the present embodiment. FIG. 2A to FIG. 2C show partially etched states, namely, states where etching is performed incompletely and is suspended in the middle. The diameter of the hole to be formed by etching is approximately 130 nm, the initial thickness of the resist is approximately 360 nm, and the film thickness of the SiOC film as a to-be-etched film is approximately 383 nm.

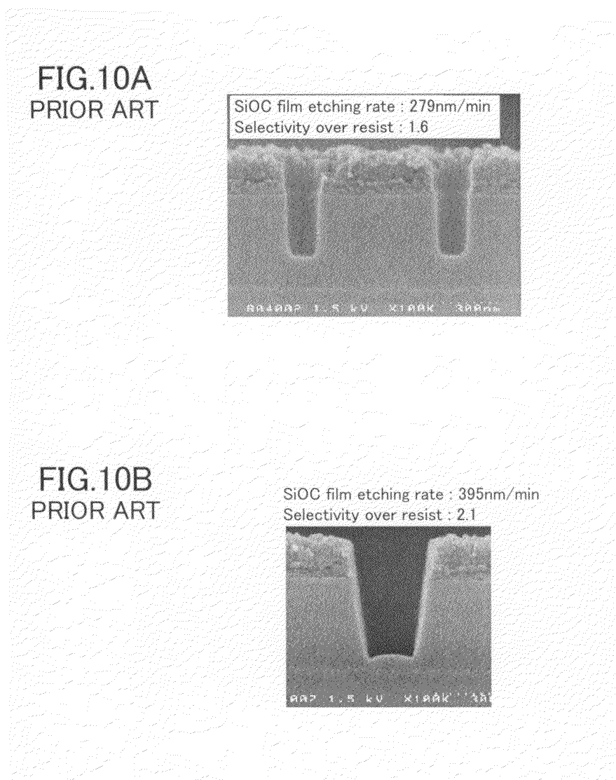

FIG. 2A shows a result of etching for hole formation by the conventional etching method which has been described for explaining the conventional example shown in FIG. 10A.

One example of the etching conditions in the conventional etching method is as follows.

[Conventional Etching Conditions 1]

Gas flow rate: CF₄/C₄F₈/N₂=50/10/50 (cm³/min. (standard conditions))

Pressure: 1.33 (Pa)

Microwave power: 2500 (W) [frequency: 2.45 GHz]

Bias power: 400 (W) [frequency: 13.56 MHz]

Substrate temperature: approximately 80° C.

In hole formation showing in FIG. 2A, the etching rate of the SiOC film is 279 nm/min., the resist etching rate is 174 nm/min., and the resist selectivity is 1.6.

For example, in the case where a hole pattern is formed by etching the SiOC film having the initial film thickness of 383 nm under the above conventional conditions, when 30% over-etching (498 nm thickness) is performed, the resist having an initial film thickness of 360 nm is etched by 311 nm (=498/1.6) to have a thickness of 49 nm (=360−311).

In detail, in the above conventional etching method, the resist selectivity is small, so that actual over-etching reduces the thickness of the resist remaining after etching. For example, in actual dual damascene (DD) processing, a via hole must be processed to have an aspect ratio (hole depth/hole diameter) of approximately 4. As well, in forming a contact hole, the hole must be formed to have a larger aspect ratio of 6. The aspect ratio of the hole in the partially etched state shown in FIG. 2A is approximately 3, and accordingly, a time period required for etching a via hole is 4/3 times the time period required for etching the hole shown in FIG. 2A. As a result, when a via hole is formed by the aforementioned conventional etching method, the resist is etched by 415 nm (=311×4/3), which means that the resist having an initial film thickness of 360 nm is removed entirely.

In contrast, a result of etching for hole formation by the etching method according to the present embodiment will be described with reference to FIG. 2B and FIG. 2C.

FIG. 2B shows a result of etching for hole formation performed under a condition where the frequency of the RF bias to be applied to the electrode 5 of the dry etching apparatus shown in FIG. 1A is set to 2 MHz. Etching conditions (etching conditions 1 of the present invention) are the same as the aforementioned conventional etching conditions 1 except the RF bias frequency, as listed below.

[Etching Conditions 1 of the Present Invention]

Gas flow rate: CF₄/C₄F₈/N₂=50/10/50 (cm³/min. (standard conditions))

Pressure: 1.33 (Pa)

Microwave power: 2500 (W) [frequency: 2.45 GHz]

Bias power: 400 (W) [frequency: 2 MHz]

Substrate temperature: approximately 80° C.

In hole formation showing in FIG. 2B, the etching rate of the SiOC film is 342 nm/min., the resist etching rate is 137 nm/min., and the resist selectivity is 2.5.

For example, in the case where a hole of which aspect ratio is 3 is formed by etching a SiOC film having an initial film thickness of 383 nm under the conditions 1 of the present invention, when 30% over-etching (498 nm thickness) is performed, the resist having an initial film thickness of 360 nm is etched by 199 nm (=498/2.5) to have a thickness of 161 nm (=360−199) after etching. As well, when a via hole of which aspect ratio is 4 is formed by etching under the conditions 1 of the present invention, the resist having an initial film thickness of 360 nm is etched by 265 nm (=199×4/3) to have a thickness of 95 nm (=360−265) after etching.

As described above, when the RF bias frequency is set to 2 MHz in the etching method of the present embodiment, the resist selectivity increases from 1.6, which is achieved in the conventional etching method (RF bias frequency is 13.56 MHz), to 2.5, thereby avoiding the problems caused due to shortage in thickness of the resist remaining after etching.

FIG. 2C shows a result of etching for hole formation performed under a condition where the frequency of the RF bias to be applied to the electrode 5 of the dry etching apparatus shown in FIG. 1A is set to 400 kHz. Etching conditions (etching condition 2 of the present invention) are the same as the aforementioned conventional etching conditions 1 except the RF bias frequency, as listed below.

[Etching Conditions 2 of the Present Invention]

Gas flow rate: CF₄/C₄F₈/N₂=50/10/50 (cm³/min. (standard conditions))

Pressure: 1.33 (Pa)

Microwave power: 2500 (W) [frequency: 2.45 GHz]

Bias power: 400 (W) [frequency: 400 kHz]

Substrate temperature: approximately 80° C.

In hole formation showing in FIG. 2C, the etching rate of the SiOC film is 338 nm/min., the resist etching rate is 135 nm/min., and the resist selectivity is 2.5. Accordingly, the same resist selectivity can be achieved as that in the case where the RF bias frequency is set to 2 MHz, which leads to the same effect in etching as in that case.

Specifically, in the case where a hole of which aspect ratio is 3 is formed by etching a SiOC film having an initial film thickness of 383 nm under the conditions 2 of the present invention, when 30% over-etching (498 nm thickness) is performed, the resist having an initial film thickness of 360 nm is etched by 199 nm (=498/2.5) to have a thickness of 161 nm (=360−199) after etching. As well, when a via hole of which aspect ratio is 4 is formed by etching under the conditions 2 of the present invention, the resist having an initial film thickness of 360 nm is etched by 265 nm (=199×4/3) to have a thickness of 95 nm (=360−265) after etching.

As described above, when the RF bias frequency is set to 400 kHz in the etching method of the present embodiment, the resist selectivity increases from 1.6, which is obtained in the conventional etching method (RF bias frequency is 13.56 MHz), to 2.5, thereby avoiding the problems caused due to shortage in thickness of the resist remaining after etching.

Though the result of the etching is not described in detail, the same effects were obtained when the RF bias frequency is set to any of 1 MHz, 800 kHz, or the like in the etching method of the present embodiment.

Thus, the etching method of the present embodiment using a RF bias frequency of 2 MHz or lower achieves hole formation by etching a SiOC film at a high resist selectivity, 2.5, which is approximately 1.6 times the resist selectivity achieved in the conventional technique, thereby achieving highly precise and safe dry etching.

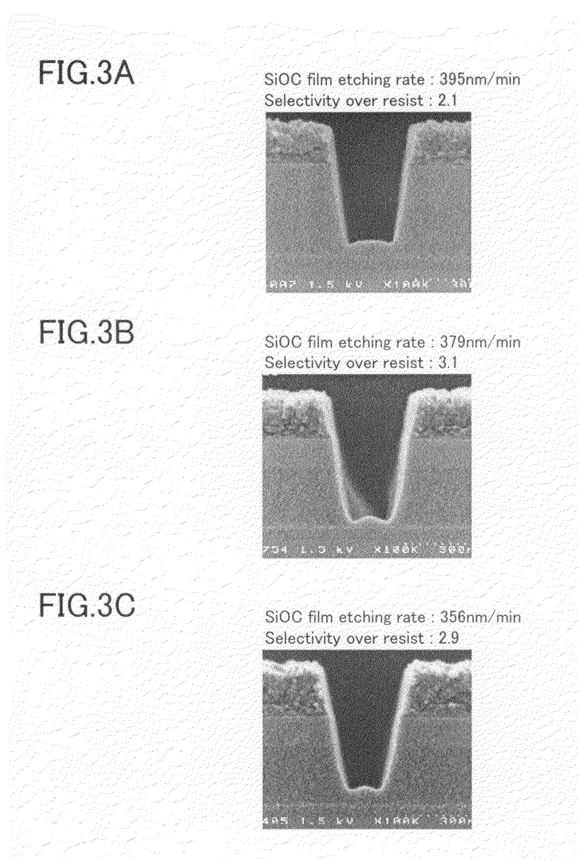

Description will be given next with reference to FIG. 3A to FIG. 3C to effects by 2 MHz or lower RF bias frequency in trench pattern formation by the etching method according to the present embodiment.

FIG. 3A to FIG. 3C are photos for explaining effects obtained when a trench pattern is formed by etching a SiOC film by the dry etching according to the present embodiment. FIG. 3A to FIG. 3C show partially etched states, namely, states where etching is performed incompletely and is suspended in the middle. The width of the trench to be formed by etching is approximately 260 nm, the initial thickness of the resist is approximately 360 nm, and the film thickness of the SiOC film as a to-be-etched film is approximately 383 nm. In short, the conditions of the initial film thickness of the resist and the film thickness of the SiOC film are the same as those in above described etching for hole formation.

FIG. 3A shows a result of etching for trench formation by the conventional etching method which has been described for explaining the conventional example shown in FIG. 10B. Herein, the etching conditions are the same as the conventional etching conditions 1, namely, the RF bias frequency is set to 13.56 MHz.

In trench formation showing in FIG. 3A, the etching rate of the SiOC film is 395 nm/min., the resist etching rate is 188 nm/min., and the resist selectivity is 2.1.

FIG. 3B shows a result of etching for trench formation performed under a condition where the frequency of the RF bias to be applied to the electrode 5 of the dry etching apparatus shown in FIG. 1A is set to 2 MHz. The etching conditions are the same as the aforementioned etching condition 1 of the present invention.

In trench formation showing in FIG. 3B, the etching rate of the SiOC film is 379 nm/min., the resist etching rate is 122 nm/min., and the resist selectivity is 3.1.

FIG. 3C shows a result of etching for trench formation performed under a condition where the frequency of the RF bias to be applied to the electrode 5 of the dry etching apparatus shown in FIG. 1A is set to 400 kHz. The etching conditions are the same as the aforementioned etching condition 2 of the present invention.

In trench formation showing in FIG. 3C, the etching rate of the SiOC film is 356 nm/min., the resist etching rate is 123 nm/min., and the resist selectivity is 2.9.

Thus, the etching method of the present embodiment using 2 MHz or lower RF bias frequency achieves trench formation by etching a SiOC film at a high resist selectivity, 2.9 or higher, which is approximately 1.4 times or more the resist selectivity achieved in the conventional technique, thereby achieving highly precise and safe dry etching.

Description will be given to effects by 2 MHz or lower RF bias frequency (low frequency RF bias) in the etching method according to the present embodiment.

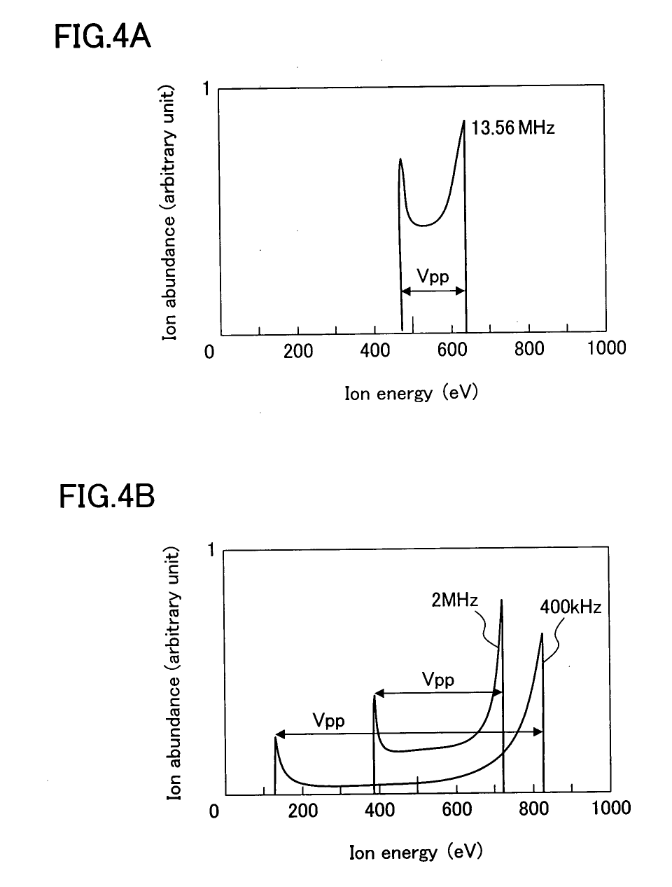

FIG. 4A and FIG. 4B are graphs for explaining effects by low frequency RF bias when the bias power is 400 W, wherein FIG. 4A shows an ion energy distribution obtained under the conventional etching conditions 1, and FIG. 4B shows ion energy distributions obtained under the etching conditions 1 of the present invention and the etching conditions 2 of the present invention. As shown in FIG. 4A and FIG. 4B, each distribution has two energy peaks at the respective ends on the high energy side and the low energy side, namely, is a generally-called bimodal distribution.

As shown in FIG. 4A, which is the ion energy distribution obtained under the conventional etching conditions 1, namely, in the case at 13.56 MHz RF bias frequency, Vpp (a peak-to-peak voltage of energy of incident ions to substrate) is 163 eV, which means narrow in energy distribution.

In contrast, as shown in FIG. 4B, the ion energy distribution obtained under the etching conditions 1 of the present invention, namely, in the case at 2 MHz RF bias frequency has Vpp of 333 eV, which means energy distribution approximately twice larger than that in the case at 13.56 MHz. Thus, with the use of 2 MHz RF bias frequency, both ions having higher energy and ions having lower energy are made incident to the substrate when compared with the case at 13.56 MHz RF bias frequency.

Further, as shown in FIG. 4B, the ion energy distribution obtained under the etching conditions 2 of the present invention, namely, in the case at 400 kHz RF bias frequency has Vpp of 701 eV, which means rather broad energy distribution, and accordingly, rather high energy ions are generated while rather low energy ions are also generated.

Herein, brief description will be given to a mechanism in etching a SiOC film by the plasma generated from the first molecule gas containing carbon and fluorine and the second molecule gas containing nitrogen in the dry etching method according to the present embodiment, which the present inventor has found. In the SiOC film etching in the present embodiment, C in the reactive surface of the SiOC film reacts with nitrogen atoms and nitrogen molecules, thereby being removed in the form of HCN, CN, or C₂N₂. Subsequently, Si—O bonds in the reactive surface after C is removed is cut by fluorine atom ions or fluorocarbon molecule ions (dominantly, CFₓ ions (x=1, 2, or 3)), thereby being removed in the form of silicon fluoride. Thus, in the SiOC film etching by the plasma generated from the first molecule gas containing carbon and fluorine and the second molecule gas containing nitrogen, two kinds of reactions are caused simultaneously and alternately, wherein one reaction is removal of carbon in the SiOC film by nitrogen atoms and molecules including nitrogen atoms generated from the second molecule gas containing nitrogen while the other reaction is removal of Si in the SiOC film by fluorine atoms ions or fluorocarbon molecule ions generated from the first molecule gas containing carbon and fluorine.

In SiO₂ film etching, when the bias power is adjusted so as to provide a maximum ion energy of approximately 1 keV to 1.5 keV, efficient etching reaction is caused. In contrast, in SiOC film etching, the reaction of removing C by ions containing nitrogen is caused at a low ion energy of approximately 150 eV to 600 eV, and accordingly, dry etching at further lower ion energy can be performed than SiO₂ film etching.

Further, in SiOC film etching, ions having high energy contribute largely to etching to Si in the SiOC film. For this reason, when a RF bias frequency of 2 MHz or 400 kHz is used, which generates ion having energy higher than those in the case using 13.56 MHz RF bias frequency, the etching rate of the SiOC film increases as shown in the results of etching in FIG. 2A to FIG. 2C. This is because: the higher the ion energy is, the larger the number of etching reaction caused by one ion becomes, and accordingly, Si—O bonds are cut efficiently and Si is removed in the form of SiFₓ.

The mechanism of etching a SiOC film in trench etching as shown in FIG. 3A to FIG. 3C is somewhat different from the above mechanism of hole etching. In trench etching, effect of restraining incidence of radical flux, which depends on the pattern configuration is smaller than that in hole etching, and accordingly, approximately five times or more radicals fly to the reactive surface when compared with those in hole etching. The flying radicals form a reaction layer on the etched surface thicker than that in the case of hole etching. For this reason, incident ions to the reactive etched surface cannot distribute to etching to the SiOC film unless etching reaction is caused after the reaction layer is removed, with a result that the threshold value of ion energy that can contribute to the etching rate becomes large. Hence, as shown in the results of etching in FIG. 3A to FIG. 3C, the low energy component in the ion energy distribution increases and the number of ions that do not distribute to etching reaction increases as the RF bias frequency becomes low, thereby lowering the etching rate of the SiOC film.

On the other hand, the resist etching rate depends on thermal reaction by radicals and reactive ion reaction and sputtering reaction by ions in general. In the dry etching method of the present embodiment, the etching species that contribute to resist etching are: radicals and ions of fluorine atoms and radicals and ions of CFₓ (x=1, 2, or 3), which are generated from the first molecule gas containing carbon and fluorine; and radicals and ions of nitrogen atoms and radicals and ions of nitrogen molecules, which are generated from the second molecule gas containing nitrogen.

Herein, no molecule gas of oxygen is used principally in the dry etching method of the present embodiment, and therefore, the aforementioned thermal reaction can be ignored substantially. Accordingly, the effect by reaction of the reactive ions of the nitrogen atoms and the nitrogen molecules and the effect by sputtering reaction by the respective ions become large. In the reaction by the reactive ions, carbon in the resist is changed to HCN, CN, or C₂N₂ with the nitrogen atom ions and the nitrogen molecule ions, thereby being removed. Besides, the reaction of fluorine atoms by the reactive ions and the sputtering reaction contribute to the resist etching rate. In this case, carbon in the resist is removed in the form of CFₓ (x=1, 2, or 3). With the use of 400 kHz RF bias frequency, which generates ions having very high energy, though contribution of the sputtering reaction to the etching rate increases to some extent in contrast to the case using RF bias frequency of another value, contribution of the reaction by the reactive ions to the resist etching rate is still dominant. The motive power of the reaction by the reactive ions is ion energy. The higher the ion energy is, the more the resist etching rate increases in principal. In other words, in view of the resist etching rate, the maximum ion energy is preferably around 800 eV or lower, which is the maximum ion energy in the case using 400 kHz RF bias frequency shown in FIG. 4B.

When the same bias power is applied, almost all ions contribute to the resist etching rate when using 13.56 MHz RF bias frequency at which the energy distribution is narrow while a part of low energy ions do not contribute to the resist etching rate when using 2 MHz or lower RF bias frequency at which the energy distribution is broad.

Hence, in the trench formation by the etching method of the present embodiment, similarly to the hole formation by the etching method of the present embodiment, the use of 2 MHz or lower RF bias frequency lowers the resist etching rate when compared with the case using 13.56 MHz RF bias frequency, resulting in increased resist selectivity. In other words, both of the hole etching and the trench etching attain significant effect of lowering the resist etching rate by low RF bias frequency though they are somewhat different from each other in mechanism of etching to a SiOC film. Accordingly, when the same bias energy (bias power) is applied, the resist selectivity is larger in the case using 2 MHz or lower RF bias frequency than in the case using 13.56 MHz RF bias frequency.

In order to attain a practical etching rate in SiO₂ etching, high bias power must be applied for generating ion energy of 1 keV or larger, as described above. Therefore, the effect of resist removal by sputtering becomes large even when the RF bias frequency is set low, so that no effect of the low RF bias frequency is exhibited.

In contrast, as described above, the present inventor has found that a SiOC film can be etched at low ion energy, has newly found the mechanism that low ion energy lowers the resist etching rate in etching using the molecule gas containing carbon and fluorine and the molecule gas containing nitrogen, and has finally found, on the basis of such findings, a SiOC film etching method achieving a high resist selectivity. In short, the effect by low frequency RF bias in SiOC film etching has been found for the first time by the present inventor.

In the dry etching method of the present embodiment, the mixed gas of the first molecule gas containing carbon and fluorine and the second molecule gas containing nitrogen is used as the etching gas. While, when a gas having a ratio of F/C is 2 or smaller, such as C₄F₈, C₅F₈, or the like is used as the first molecule gas containing carbon and fluorine, the effects by low frequency RF bias can be obtained even if a trace amount of oxygen molecules are mixed therewith. In contrast, when a gas having a ratio of F/C exceeding 2, such as CF₄, CHF₃, or the like is used, it is preferable to mix no oxygen molecules. This is because distribution of the thermal reaction of oxygen atom radicals and oxygen molecule radicals to the resist etching rate is dominant when compared with the other radicals.

Further, in the dry etching method of the present embodiment, though the case using the SiOC film as a to-be-etched film has been exampled, the mechanism of etching is principally the same in the case where the to-be-etched film is another insulting film of which main compositions are Si and C, such as a SiOCN film, a SiCO film, a SiCON film, a SiC film, a SiCN film, or the like, resulting in the same effect obtained.

Moreover, in the dry etching method of the present embodiment, it is comparatively easy to increase the resist selectivity by lowering the temperature of the substrate (wafer). The substrate lowered in temperature, however, leads to shortage of radical supply to the side wall and the bottom of the pattern having a high aspect ratio to cause problems of bowing, undesirable selectivity with respect to the underlying film at the bottom of the pattern having the high aspect ratio, and the like. For this reason, excessively low temperature of the substrate is not preferable. In order to attain the entirely balanced etching characteristics in the present embodiment, the temperature of the substrate is preferably set in the range between approximately 10° C. and approximately 100° C., more preferably, in the range between approximately 25° C. and approximately 85° C. Particularly, the range between 40° C. and 85° C. is preferable for processing a pattern having a high aspect ratio.

### Embodiment 2

A dry etching method according to Embodiment 2 of the present invention will be described with reference to the drawings by referring to the case using a SiOC film as a to-be-etched film.

In the present embodiment, similarly to Embodiment 1, for dry etching an insulating film of which main compositions are Si and C, such as a SiOC film or the like, a low frequency RF bias of 2 MHz or lower is applied to an electrode on which a wafer is placed while plasma is generated from a mixed gas of a molecule gas containing carbon and fluorine and a molecule gas containing nitrogen.

Difference of the present embodiment from Embodiment 1 lies in that the RF bias power is set to, for example, 250 W to set the maximum energy of incident ions to the insulating film from the plasma by the RF bias to 600 eV or lower. Specifically, etching conditions of the present embodiment (etching conditions 3 of the present invention) are the same as those of the etching conditions in Embodiment 1 (the etching conditions 1 of the present invention or the etching conditions 2 of the present invention) except the RF bias power, as listed below.

[Etching Conditions 3 of the Present Invention]

Gas flow rate: CF₄/C₄F₈/N₂=50/10/50 (cm³/min. (standard conditions))

Pressure: 1.33 (Pa)

Microwave power: 2500 (W) [frequency: 2.45 GHz]

Bias power: 250 (W) [frequency: f]

Substrate temperature: approximately 80° C.

Effects by the dry etching method according to the present embodiment different from those in Embodiment 1 will be described below with reference to the drawings.

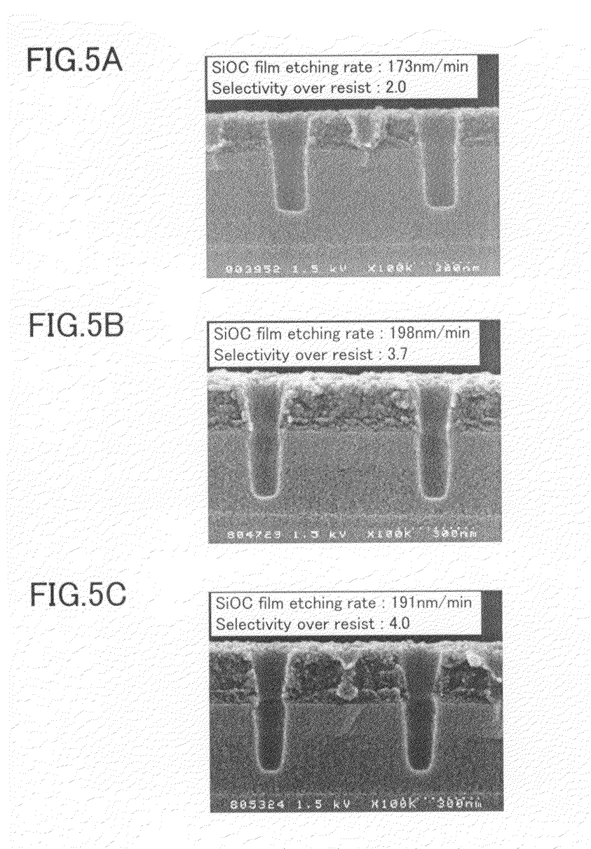

FIG. 5A to FIG. 5C are photos for explaining effects obtained when a hole pattern is formed by etching a SiOC film by the dry etching method of the present embodiment, wherein FIG. 5A shows a result of etching for hole formation where the RF bias frequency f of the etching conditions 3 of the present invention is set to 13.56 MHz as a comparative example, FIG. 5B shows a result of etching for hole formation where the RF bias frequency f of the etching conditions 3 of the present invention is set to 2 MHz, and FIG. 5C shows a result of etching for hole formation where the RF bias frequency f of the etching conditions 3 of the present invention is set to 400 kHz. FIG. 5A to FIG. 5C shows partially etched states, namely, states where etching is performed incompletely and is suspended in the middle. The diameter of the hole to be formed by etching is approximately 130 nm, the initial thickness of the resist is approximately 360 nm, and the film thickness of the SiOC film as a to-be-etched film is approximately 383 nm.

In hole formation shown in FIG. 5A (RF bias frequency f is 13.56 MHz), the etching rate of the SiOC film is 173 nm/min., the resist etching rate is 87 nm/min., and the resist selectivity is 2.0.

In contrast, in hole formation shown in FIG. 5B (RF bias frequency f is 2 MHz), the etching rate of the SiOC film is 198 nm/min., the resist etching rate is 54 nm/min., and the resist selectivity is 3.7.

Further, in hole formation shown in FIG. 5C (RF bias frequency f is 400 kHz), the etching rate of the SiOC film is 191 nm/min., the resist etching rate is 48 nm/min., and the resist selectivity is 4.0.

Thus, the use of the RF bias frequency of 2 MHz in the etching method of the present embodiment achieves hole etching to the SiOC film at a high resist selectivity of 3.7. The resist selectivity of 3.7 corresponds to 2.3 times the resist selectivity of 1.6 achieved in the conventional etching method shown in FIG. 2A.

Similarly, the use of the RF bias frequency of 400 kHz in the etching method of the present embodiment achieves a higher resist selectivity of 4.0, which corresponds to 2.5 times the resist selectivity of 1.6 achieved in the conventional etching method shown in FIG. 2A.

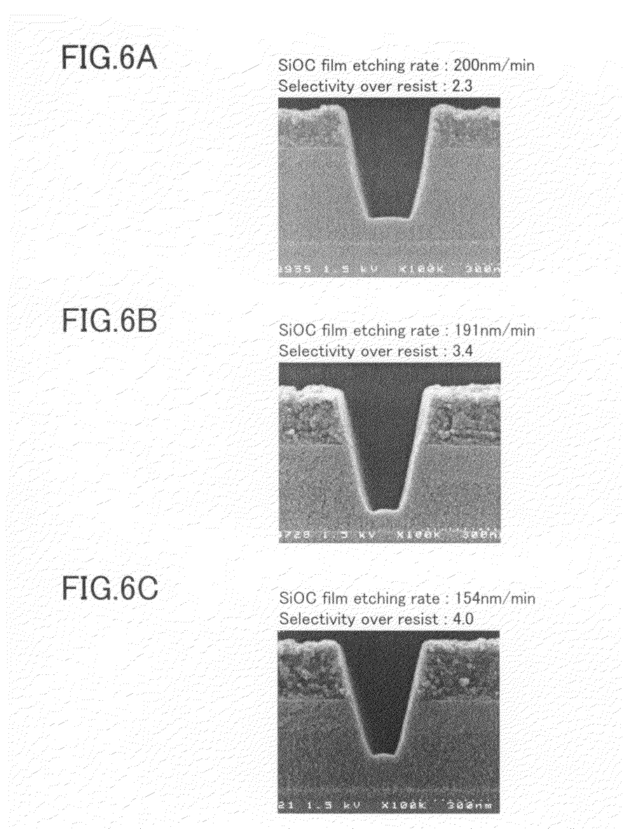

FIG. 6A to FIG. 6C are photos for explaining effects obtained when a trench pattern is formed by etching a SiOC film by the dry etching method of the present embodiment, wherein FIG. 6A shows a result of etching for trench formation where the RF bias frequency f of the etching conditions 3 of the present invention is set to 13.56 MHz as a comparative example, FIG. 6B shows a result of etching for trench formation where the RF bias frequency f of the etching conditions 3 of the present invention is set to 2 MHz, and FIG. 6C shows a result of etching for trench formation where the RF bias frequency f of the etching conditions 3 of the present invention is set to 400 kHz. FIG. 6A to FIG. 6C shows partially etched states, namely, states where etching is performed incompletely and is suspended in the middle. The width of the trench to be formed by etching is approximately 260 nm, the initial thickness of the resist is approximately 360 nm, and the film thickness of the SiOC film as a to-be-etched film is approximately 383 nm.

In trench formation shown in FIG. 6A (RF bias frequency f is 13.56 MHz), the etching rate of the SiOC film is 200 nm/min., the resist etching rate is 87 nm/min., and the resist selectivity is 2.3.

In contrast, in trench formation shown in FIG. 6B (RF bias frequency f is 2 MHz), the etching rate of the SiOC film is 191 nm/min., the resist etching rate is 56 nm/min., and the resist selectivity is 3.4.

Further, in trench formation shown in FIG. 6C (RF bias frequency f is 400 kHz), the etching rate of the SiOC film is 154 nm/min., the resist etching rate is 39 nm/min., and the resist selectivity is 4.0.

Thus, the use of the RF bias frequency of 2 MHz in the etching method of the present embodiment achieves a high resist selectivity of 3.4 in trench etching to the SiOC film. The resist selectivity of 3.7 corresponds to 1.6 times the resist selectivity of 2.1 achieved in the conventional etching method shown in FIG. 3A.

Similarly, the use of the RF bias frequency of 400 kHz in the etching method of the present embodiment achieves a higher resist selectivity of 4.0, which corresponds to 1.9 times the resist selectivity of 2.1 achieved in the conventional etching method shown in FIG. 3A.

The effects by 2 MHz or lower RF bias frequency (low frequency RF bias) in the etching method of the present embodiment will be described below.

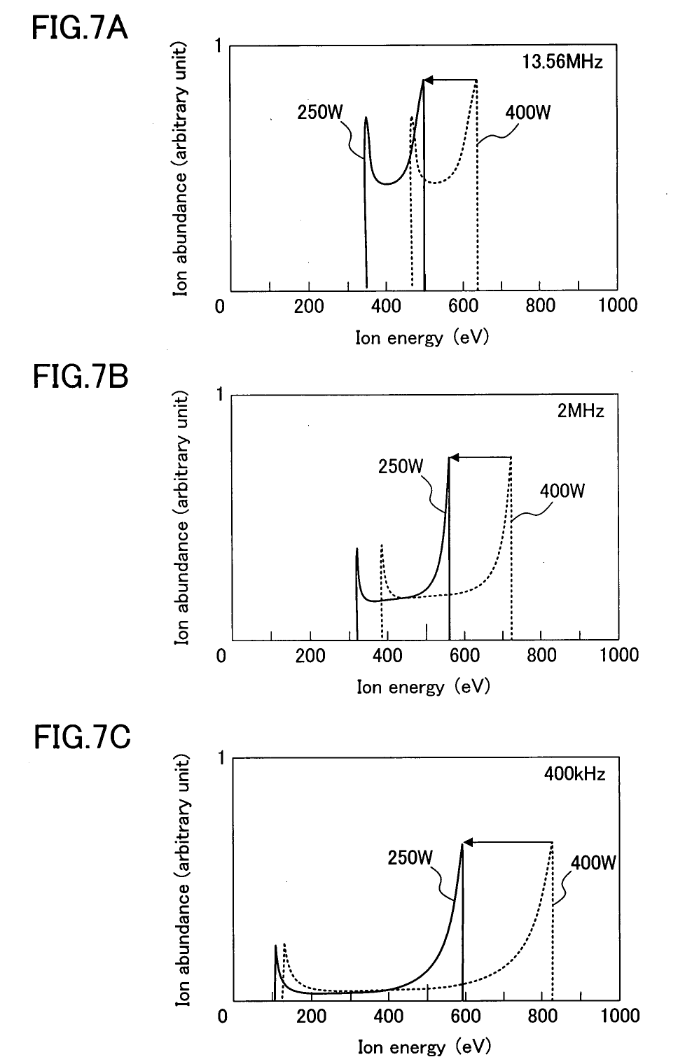

FIG. 7A to FIG. 7C are graphs for explaining the effects by low frequency RF bias at a bias power of 250 W in comparison with those at a bias power of 400 W, wherein FIG. 7A shows ion energy distributions where the RF bias frequency f of the etching conditions 3 of the present invention is set to 13.56 MHz as a comparative example, FIG. 7B shows ion energy distributions where the RF bias frequency f of the etching conditions 3 of the present invention is set to 2 MHz, and FIG. 7C shows ion energy distributions where the RF bias frequency f of the etching conditions 3 of the present invention is set to 400 kHz.

As shown in FIG. 7A, in the case where the RF bias frequency f is set to 13.56 MHz, when the bias power is reduced from 400 W to 250 W, the peak on the high energy side in the ion energy distribution lowers by about 130 eV. As a result, the etching rate of the SiOC film at a bias power of 250 W (see FIG. 5A) lowers 0.62 time (=173/279) the etching rate of the SiOC film at a bias power of 400 W (see FIG. 2A). Though Vpp is reduced from 163 eV to 136 eV, the reduced peak on the low energy side is 350 eV or so because the energy distribution is narrow originally. Accordingly, the etching rate at a bias power of 250 W reduces to approximately one half (=87/174) of the resist etching rate at a bias power of 400 W.

Referring to FIG. 7B, in contrast, in the case where the RF bias frequency f is set to 2 MHz, when the bias power is reduced from 400 W to 250 W, the ion energy distribution shifts toward the lower side as a whole, as well, and Vpp also lowers from 333 eV to 229 eV. As a result, the etching rate of the SiOC film at a bias power of 250 W (see FIG. 5B) lowers 0.58 time (=198/342) the etching rate of the SiOC film at a bias power of 400 W (see FIG. 2B). Further, the resist etching rate at a bias power of 250 W lowers to approximately 0.39 time (=54/137) the resist etching rate at a bias power of 400 W.

When the result shown in FIG. 7B (RF bias frequency f is 2 MHz) is compared with the result shown in FIG. 7A (RF bias frequency f is 13.56 MHz), though no significant difference is admitted in etching rate of the SiOC film between the case at 2 MHz RF bias frequency and the case at 13.56 RF bias frequency because the values of the ion energy at the peak on the high energy side thereof approximate to each other, the case at 2 MHz RF bias frequency at which ion energy at the peak on the high energy side is high is higher in the etching rate of the SiOC film than the case at 13.56 MHz RF bias frequency (see FIG. 5A and FIG. 5B). Further, in the case where the RF bias frequency f is set to 2 MHz, when the bias power is reduced from 400 W to 250 W, the etching rate of the SiOC film lowers 0.58 time while the resist etching rate lowers more largely, namely, 0.39 time. This is because of the effect by shifting of the entire ion energy distribution toward the low energy side and the effect by an increase in rate of the low energy ion component.

In addition, as shown in FIG. 7C, in the case where the RF bias frequency f is set to 400 kHz, when the bias power is reduced from 400 W to 250 W, the ion energy distribution shifts to the lower side as a whole and Vpp lowers from 701 eV to 496 eV. As a result, the etching rate of the SiOC film at a bias power of 250 W (see FIG. 5C) lowers 0.57 time (=191/338) the etching rate of the SiOC film at a bias power of 400 W (see FIG. 2C). As well, the etching rate at a bias power of 250 W lowers approximately 0.36 time (=48/137) the resist etching rate at a bias power of 400 W.

When the result shown in FIG. 7C (RF bias frequency f is 400 kHz) is compared with the result shown in FIG. 7B (RF bias frequency f is 2 MHz), the energy distribution in the case at 400 kHz RF bias frequency spreads approximately 2.2 times (=496/229) larger than that in the case at 2 MHz RF bias frequency while the case at 400 kHz RF bias frequency is slightly higher than that at 2 MHz RF bias frequency in ion energy at the peak on the high energy side. Accordingly, the amount of high energy ions is smaller and the amount of low energy ions that do not contribute to the reaction is larger in the case at 400 kHz RF bias frequency than in the case at 2 MHz RF bias frequency. Since ions having high energy in the vicinity of ion energy at the peak on the high energy side are dominant in SiOC film etching, substantially the same etching rate is achieved in both the case at 400 kHz RF bias frequency and the case at 2 MHz bias frequency. On the other hand, resist etching receives influence of an increased amount of low energy ions that do not contribute to the reaction, so that the resist etching rate lowers in the case at 400 kHz RF bias frequency when compared with the case at 2 MHz RF bias frequency.

The results of hole etching shown in FIG. 5A to FIG. 5C have been examined with reference to the ion energy distributions shown in FIG. 7A to FIG. 7C. The results of trench etching shown in FIG. 6A to FIG. 6C will be examined next. The dependency of the resist etching rate on the RF bias frequency in trench etching is the same as that in hole etching, and therefore, the description thereof is omitted. As described in Embodiment 1, five times or more radical flux are present in trench etching to the SiOC film when compared with the case of hole etching, and accordingly, the reaction layer formed on the to-be-etched surface becomes large in thickness. Therefore, the ion incident in the etched surface cannot contribute to SiOC film etching unless etching reaction is caused after the reaction layer is removed, so that the threshold value of the energy of ions that can contribute to etching rate increases. For this reason, as shown in the results of etching in FIG. 6A to FIG. 6C, the low energy component in the ion energy distribution increases and the number of ions that do not contribute to etching reaction increases as the RF bias frequency becomes low, thereby lowering the etching rate of the SIOC film. This logic is the same as that the results of etching at a RF bias power of 400 W as shown in FIG. 3A to FIG. 3C.

When the result of etching at a RF bias power of 250 W as shown in FIG. 5A to FIG. 5C are compared with the result of etching at a RF bias power of 400 W as shown in FIG. 2A to FIG. 2C, it is found that notably less surface roughness of the resist is observed in the case at 250 W RF bias frequency, which is due to reduced bias power. In other words, as can be understood from FIG. 7A to FIG. 7C, when the maximum energy of incident ions to the insulating film from the plasma by RF bias is set to 600 eV or lower, the surface of the resist becomes smooth after etching. Comparison between the results of etching shown in FIG. 3A to FIG. 3C and the results of etching shown in FIG. 6A to FIG. 6C proves that this effect by reduced ion energy is obtained in trench etching sufficiently.

The bias power of 400 W used in the comparative example in description of the present embodiment might be low in the conventional technique. When the RF bias power is set larger than 400 W, the surface roughness of the resist becomes severe, of course. The severer surface roughness of the resist will involve a further problem of striation (roughness in strips) at the side wall of the pattern.

In the present embodiment, as described above, in dry etching an insulating film of which main compositions are Si and C, such as a SiOC film or the like, a low frequency RF bias of 2 MHz or lower is applied to the electrode on which the wafer is placed, and the maximum energy of incident ions to the insulating film from the plasma by the RF bias is set to 600 eV or lower while the plasma is generated from the mixed gas of the molecule gas containing carbon and fluorine and the molecule gas containing nitrogen. As a result, there are achieved both hole etching to the SiOC film at resist selectivity approximately twice or more and trench etching to the SiOC film at resist selectivity approximately 2.5 times the resist selectivity in the conventional technique.

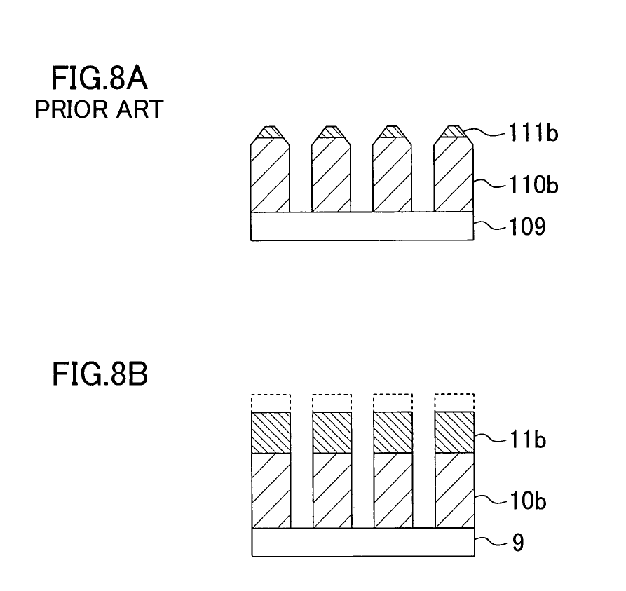

FIG. 8A shows one example of a result of hole etching by the conventional technique, and FIG. 8B shows one example of a result of hole etching in the present embodiment. In the conventional technique, as shown in FIG. 8A, the edges of the resist 111b remaining on the SiOC film 110b formed on the substrate 109 after etching are etched away to cause the upper part of the SiOC film 110b to be etched, with a result of increased opening area of the holes. In contrast, in the present embodiment, the resist 11b remaining on the SiOC film 11b formed on the substrate 9 after etching is secured in thickness sufficiently, as shown in FIG. 8B, which means achievement of highly precise etching without causing abnormality in pattern form and the like. Further, with the use of a low frequency RF bias of 2 MHz or lower, which is set so that all ions have low ion energy of approximately 600 eV or lower, the resist is etched with no surface roughness caused, which means achievement of highly precise and safe dry etching to the SiOC film.

In the dry etching method according to the present embodiment, the usable etching gases are the same as those in Embodiment 1.

Further, in the dry etching method according to the present embodiment, though the SiOC film is used as a to-be-etched film, the same effects can be obtained even when the to-be-etched film is any other insulating film of which main compositions are Si and C, such as a SiOCN film, a SiCO film, a SiCON film, a SiC film, a SiCN film, or the like, because the etching mechanism is the same in principal.

Moreover, in the dry etching method of the present embodiment, it is comparatively easy to increase the resist selectivity by lowering the temperature of the substrate (wafer). The substrate lowered in temperature, however, leads to shortage of radical supply to the side wall and the bottom of the pattern having a high aspect ratio to cause a problems of bowing, undesirable selectivity with respect to the underlying film at the bottom of the pattern having the high aspect ratio, and the like. Therefore, excessively low temperature of the substrate is not preferable. In order to achieve the entirely balanced etching characteristics in the present embodiment, the temperature of the substrate is preferably set in the range between approximately 10° C. and approximately 100° C., more preferably, in the range between approximately 25° C. and approximately 85° C. Particularly, the range between 40° C. and 85° C. is preferable for processing a pattern having a high aspect ratio.

What is claimed is:

1. A dry etching method for dry etching an insulating film containing silicon and carbon and formed on a wafer, comprising the steps of:
applying a RF bias of 2 MHz or lower to an electrode on which the wafer is placed while generating plasma from a mixed gas of a first molecule gas containing carbon and fluorine and a second molecule gas containing nitrogen.

2. A dry etching method for dry etching an insulating film containing silicon and carbon and formed on a wafer, comprising the steps of:
applying a RF bias to an electrode on which the wafer is placed while generating plasma from a mixed gas of a first molecule gas containing carbon and fluorine and a second molecule gas containing nitrogen,
wherein the RF bias has a frequency that produces a peak-to-peak voltage of ion energy distribution in the plasma, and
the peak-to-peak voltage is twice larger than that when an RF bias having a frequency of 13.56 MHz is applied to the electrode.

3. A dry etching method for dry etching an insulating film containing silicon and carbon and formed on a wafer, comprising the steps of:
applying RF bias to an electrode on which the wafer is placed so as to set a peak-to-peak voltage of ion energy distribution in the plasma to 200 eV or higher while generating plasma from a mixed gas of a first molecule gas containing carbon and fluorine and a second molecule gas containing nitrogen.

4. The dry etching method of claim 1,
wherein a maximum energy of incident ions to the insulating film from the plasma by the RF bias is set to 600 eV or lower.

5. The dry etching method of claim 1,
wherein the mixed gas further contains a hydrocarbon molecule gas.

6. The dry etching method of claim 5,
wherein the hydrocarbon molecule gas is CH₄, C₂H₄, or C₂H₆.

7. The dry etching method of claim 5,
wherein a gas containing fluorine and a hydrocarbon molecule is used in place of the first molecule gas and the hydrocarbon molecule gas.

8. The dry etching method of claim 1,
wherein the first molecule gas is a fluorocarbon gas or a hydride fluorocarbon gas.

9. The dry etching method of claim 1,
wherein the second molecule gas is a molecule gas of nitrogen or an ammonia gas.

10. The dry etching method of claim 1,
wherein the second molecule gas is a molecule gas containing a C—N bond and hydrogen.

11. The dry etching method of claim 10,
wherein the second molecule gas containing a C—N bond and hydrogen is an amine compound gas or a nitrile compound gas.

12. The dry etching method of claim 1,
wherein a gas containing fluorine and nitrogen is used in place of the first molecule gas and the second molecule gas.

13. The dry etching method of claim 1,
wherein the mixed gas further contains a rare gas.

14. The dry etching method of claim 1,
wherein the insulating film is a SiOC film, a SiOCN film, a SiCO film, SiCON film, a SiC film or a SiCN film.
